(19) United States
(12) Patent Application Publication
(10) Pub. No.: US 2010/0124022 A1
(43) Pub. Date: May 20, 2010

(54) THERMOELECTRIC COOLING APPARATUS AND METHOD FOR COOLING AN INTEGRATED CIRCUIT

(76) Inventor: Suad Causevic, Chicago, IL (US)

Correspondence Address: K&L Gates LLP, P.O. Box 1135, CHICAGO, IL, 60690, US

(21) Appl. No.: 12/619,398

(22) Filed: Nov. 16, 2009

Related U.S. Application Data
(60) Provisional application No. 61/114,846, filed on Nov. 14, 2008.

(51) Int. Cl. H05K 7/20

(52) U.S. Cl. 361/702; 361/689

(57) ABSTRACT

A computer system and method that cools an integrated circuit by use of a pipe and thermoelectric cooling module. Heat is moved from an integrated circuit and eventually dissipated into the air by fluid circulated in a pipe in thermal contact with the integrated circuit and the thermo-electric cooling module. In an embodiment, fluid is pumped by a magneto-hydrodynamic pump assembly.

### RELATED APPLICATION

This application claims the benefit of U.S. Provisional application number 61/114,846, filed Nov. 14, 2008, which is incorporated by reference in its entirety herein.

### BACKGROUND

The present application relates to a computer system with a cooling apparatus that cools an integrated circuit. In particular, the present application relates to a computer system with a cooling apparatus that cools an integrated circuit using a pipe and a thermoelectric cooling module.

In addition, the present application relates to a method of cooling an integrated circuit. In particular, the present application relates to a method that cools an integrated circuit by circulating fluid in a pipe in thermal contact with the integrated circuit and a thermoelectric cooling module.

Integrated circuits, also known as microchips, silicon chips, microcircuits, or chips, have consistently migrated to smaller feature sizes and form factors over the past several years allowing for more transistors to be packaged in a single integrated circuit. Electricity passing through transistors generates heat. Heat dissipation requirements also tend to increase as transistor switching speeds become faster. Because the density of transistors within a single integrated circuit is continuing to increase, as is the operational switching speed of these transistors, an ever-increasing significant amount of heat must be dissipated to reduce the possibility of undesired consequences such as overheating, melting, or system crashes.

Heat sinks and fans are commonly used to dissipate heat generated by integrated circuits, however they are subject to mechanical failure and dust build-up after prolonged use. In addition, cooling approaches that employ active mechanisms such as fans tend to have a certain amount of noise associated with their operation. This noise can range from being merely annoying to highly distracting.

In addition, heat sinks and fans have limited heat dissipation capacity limited to the surface area of the heat sink and the amount of air circulated by the fan.

### SUMMARY

An advantage of the present application is to provide a computer apparatus with a cooling apparatus and a method capable of cooling an integrated circuit without mechanical moving parts that are subject to mechanical failure or dust build-up after prolonged use.

The computer apparatus according to an embodiment combines an integrated circuit with a cooling apparatus. The cooling apparatus includes: a thermoelectric cooling module, a heat sink, a fluid-bearing pipe, a magneto-hydrodynamic pump assembly, a heat exchange attachment and a reservoir for additional fluid.

Additional features and advantages are described herein, and will be apparent from the following Detailed Description and the figures.

### BRIEF DESCRIPTION OF THE FIGURES

FIG. 1 is a perspective view of a computer system with a cooling apparatus of one embodiment of the present disclosure.

FIG. 2 is a perspective view of a heat exchange attachment of one embodiment of the present disclosure.

FIG. 3 is a cross sectional view of magneto-hydrodynamic heat pump assembly of one embodiment of the present disclosure.

FIG. 4 is a perspective view of a thermoelectric cooling module of one embodiment of the present disclosure

### DETAILED DESCRIPTION

An embodiment of the present application will be described in detail with reference to the accompanying drawings.

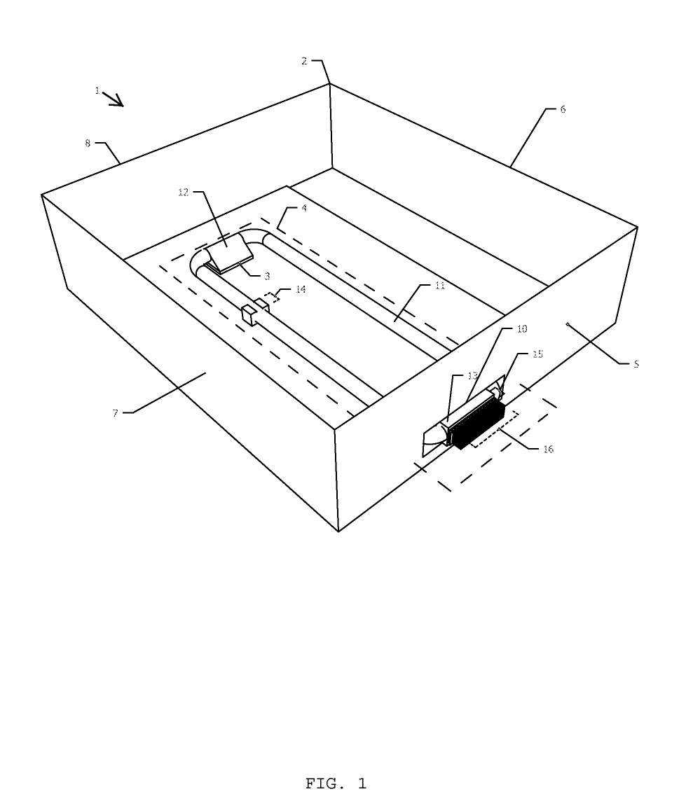

FIG. 1 shows a computer apparatus 1 according to an embodiment. Computer apparatus 1 as shown in FIG. 1 includes a case 2, an integrated circuit 3 and a cooling apparatus 4.

The case 2 further includes a first side 5, a second side 6, a third side 7, a fourth side 8 and a fifth side 9. While computer system 1 in FIG. 1 is shown without a sixth side, an embodiment may include a sixth side as well as a wall covering all sides of a computer system including the sixth side. The walls may be solid or hollow, but are commonly metal or plastic or a combination thereof. The first side 5, as shown in FIG. 1, also includes an opening 10 therethrough to allow a portion of the cooling apparatus to extend outside case 2.

In addition, while FIG. 1 shows the computer apparatus 1 in a horizontal desktop position, a computer apparatus in an embodiment could be in vertical tower position. Furthermore, the form factor for the computer apparatus in an embodiment could be a laptop, a rack-mount server, a desktop or the like.

The integrated circuit 3 in FIG. 1 is a central processing unit (CPU) and is shown as being at least partially enclosed by the case 2. While this integrated circuit 3 in FIG. 1 is a CPU, an integrated circuit in an embodiment could be a graphics processing unit (GPU) or any other microchip that requires cooling.

The cooling apparatus 4 in the embodiment includes a pipe 11, a heat exchange attachment 12, a reservoir 13, a magneto-hydrodynamic pump assembly 14, a thermoelectric cooling module 15 and a heat sink 16.

Pipe 11 as shown in FIG. 1 is arranged to circulate fluid in order to carry heat away from the integrated circuit 3 to the thermoelectric cooling module 15. A portion of this pipe 11 extends through the aforementioned opening 10 (and hence the pipe 11 is partially outside of the case 2) thereby allowing for more efficient heat dissipation. While FIG. 1 shows a single pipe having a 1 inch diameter, an embodiment may include a single pipe having other diameters or even multiple pipes of uniform or varying diameters. In addition, in an embodiment the pipe may be completely enclosed by the case 2 rather than partially extending therefrom as shown here. This pipe 11 could be metal, glass, plastic or any other material of choice. Depending on the fluid within the pipe, metal may be preferred because of the expansive characteristic of many liquids when heated.

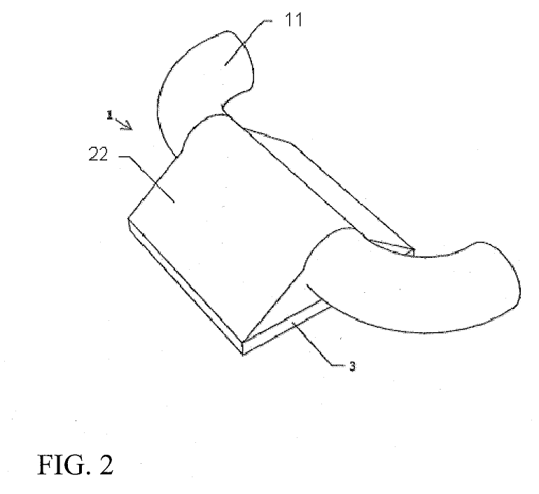

The heat exchange attachment 12, as shown in FIG. 1, is connected to the pipe 11. As further shown in FIG. 2, the heat exchange attachment 12 includes a fluid-containing reservoir 22 wherein the pipe 11 enters and exits the reservoir 22. So configured, fluid within the pipe 11 can similarly enter the reservoir 22 and then exit accordingly.

A planar surface of reservoir 22 comprises a heat-exchange medium that is in direct physical contact with the integrated circuit 3 and hence there is good thermal contact between the reservoir 22 and the integrated circuit 3. This reservoir 22, at least at this point of physical contact, may be made of a heat conductive material such as a suitable metal. While the embodiment shows the heat exchange attachment 12 as comprising a reservoir 22, there are other possibilities. For example, the heat exchange attachment 12 could be a fin heat sink, or a portion of the pipe 11 that is shaped and disposed to be in thermal contact with an integrated circuit 3.

Referring again to FIG. 1, the early-mentioned reservoir 13 contains additional fluid. As shown in FIG. 1, this reservoir 13 is connected to the pipe 11 and is in direct physical and thermal contact with the thermo-electric cooling module 15. This reservoir 13 may be metal or plastic, or a combination thereof. In an embodiment, the additional fluid in this reservoir 13 increases the heat-absorption capacity of the cooling apparatus 4. This reservoir 13 is optional and in an embodiment, this reservoir 13 for additional fluid need not be part of the cooling apparatus.

The magneto-hydrodynamic pump assembly 14 as shown in FIG. 1 connects to a portion of the pipe 11. Magneto-hydrodynamics generally refers to the behavior of a plasma, or, in general, any electrically-conducting fluid in the presence of electric and magnetic fields. Accordingly, this magneto-hydrodynamic pump assembly utilizes such fields to effect the movement of an electrically-conductive fluid of choice. This fluid, in turn, serves as a carrier to move heat from the integrated circuit to the thermoelectric cooling module 15.

While FIG. 1 shows this magneto-hydrodynamic pump assembly 14 to be connected to a portion of the pipe 11 between the heat-exchange attachment 12 and the thermoelectric cooling module 15, a pump in an embodiment could be located at any portion of the pipe 11. In addition, an embodiment could use an ordinary fluid pump instead of a magneto-hydrodynamic pump assembly. It will also be understood that more than one such pump assembly could be employed if desired.

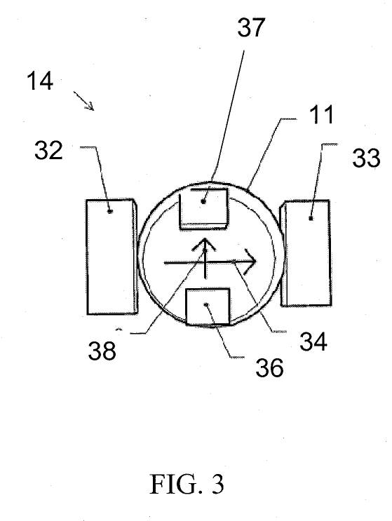

FIG. 3. is a cross section of a magneto-hydrodynamic pump assembly according to an embodiment. In this illustrative example, the magneto-hydrodynamic pump assembly 14 includes a pair of mutually attractive magnets 32, 33 positioned to create a magnetic field 34 across the pipe 11, and a pair of electrodes 36, 37 used to generate an electric current 38 through the aforementioned magnetic field 34. These magnets 32, 33 may be permanent magnets or electromagnets. Generally speaking, for many application settings, the permanent magnet (such as a neodymium magnet) may be preferred since an electromagnet might interfere with the perpendicular electric field needed to effectively circulate the fluid.

Together, the electric current 38 and the magnetic field 34 exert a force on a fluid within the pipe 11 that is perpendicular to the electric current 38 and the magnetic field 34, thereby circulating the fluid through the pipe 11. The amount of the force depends on the strength of the magnetic field 34 and the electric current 38. Generally, the greater the strength of the magnetic field 34 or the electric current 38, the greater the force exerted on the fluid in the pipe 11.

The movement and circulation of an electrically conductive liquid by use of a magneto-hydrodynamic pump is achieved through the effects of Lorentz Force. The Lorentz Force can be represented as F=qE+qv×B, where F is the magnitude and direction of force, qE is the magnitude and direction of the electric current 38, qv is the velocity of the current, and B is the magnitude and direction of the magnetic field 34. In an embodiment, the magneto-hydrodynamic pump assembly could include a plurality of electrodes as well as a plurality of magnets.

A magneto-hydrodynamic pump assembly works well with an electrically conductive fluid such as a liquid metal (for example, mercury (Hg)), but in an embodiment the fluid could be water, salt-water (such as water having 2% or so salinity), or any other thermally and electrically conductive fluid. Depending upon the application setting, one could also consider employing ionized gas as the electrically conductive fluid. In an embodiment, a magneto-hydrodynamic pump assembly could include magnets that are coated in a magnetic-shielding material such as Mu-metal to reduce the likelihood of interfering with other magnetically-sensitive components of the computer system.

As noted above, the thermo-electric cooling module 15 as shown in FIG. 1 is in thermal contact with a surface of reservoir 13 which extends outside case 2 through opening 10. Generally speaking, a thermoelectric cooler is a device that allows for the transfer of thermal energy from one of its sides to another, resulting in one cold side and one hot side. Accordingly, the basic design of a thermoelectric cooler typically comprises two main sides. Both of these sides are often made of ceramic plating. In between these two sides there are usually anywhere from two to over one hundred metal semiconductor cubes, also known as pellets. These cubes are attached to thin copper strips that alternate vertically, each containing two cubes. This chain forms a complete circuit and allows electricity to pass through the thermoelectric cooler.

Typically, half of these semiconductor cubes are P-type semiconductors and the other half are N-type semiconductors. Both the P-type and N-type semiconductor crystals in their entirety are electrically neutral. These materials, however, have impurities that result in an excess or deficit of electrons. When a direct current is applied to a thermoelectric cooler, electrons flow from the negative side of the circuit, through the N-type cube, through the opposite copper strip, through the P-type cube in the other direction, and back to the positive side of the circuit. As electrons are passing through the N-type cubes, thermal energy is transferred in the direction opposite of the current flow from one ceramic plate to the other. When these electrons reach the P-type cubes, they easily flow through the holes and thermal energy is transferred along with them. Those skilled in the art will recognize this as a practical application of the Peltier effect.

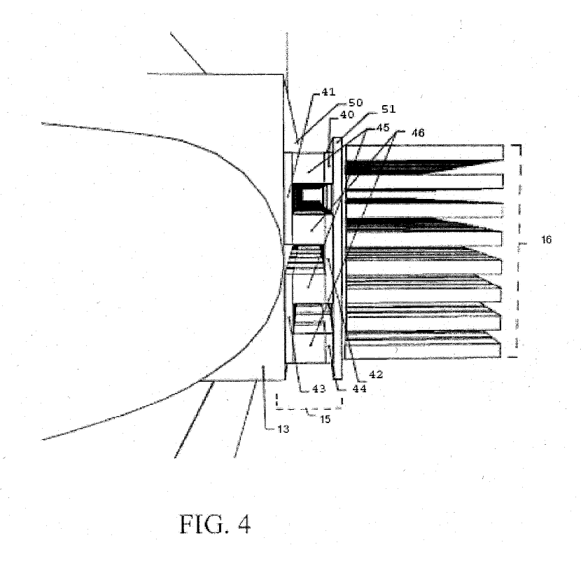

As shown in FIG. 4, by one approach this thermo-electric cooling module 15 consists of a plurality of n-type 45 and p-type 46 semiconductors connected in a series circuit. As current travels through the corresponding p-type and n-type junctions 40, 41, 42, 43 of these semiconductors, electrons lose or gain energy depending on the direction of the current. This results in cooling or heating at these junctions 40, 41, 42, 43. These junctions 40, 41, 42, 43 are arranged such that there is a cold side 50 and a hot side 51. The cold side 50 is in thermal contact with the reservoir 13, and the hot side 51 is in thermal contact with the heat sink 16. While FIG. 4 shows this cold side 50 as comprising a surface of the reservoir 16, in an embodiment the cold side of the thermo-electric cooling module could be separate layer.

As further shown in FIG. 4, the heat sink 16 is a common fin-based heat sink allowing for the absorption and dissipation of heat from the thermoelectric cooling module into the surrounding air. This thermoelectric cooling module 15 therefore serves to pump heat from the pipe 11 to the heat sink 16.

So configured, an increased quantity of heat can be ready dissipated in application settings where the heat-generating components are typically small (and getting smaller). It will be appreciated that these teachings also yield an essentially silent approach to heat-dissipation. These approaches are highly scalable and can be usefully employed in a wide variety of application settings.

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A computer apparatus comprising:
an integrated circuit at least partially enclosed by a case;
an integrated-circuit cooling apparatus comprising:
a pipe wherein at least a portion of the pipe is outside of the case;
a thermoelectric cooling module utilizing the Peltier effect thermally coupled to the portion of pipe outside of the case.

2. The computer apparatus of claim 1, the integrated-circuit cooling apparatus further comprising:
a heat-exchange medium thermally coupled to the integrated circuit;
sections of the pipe carrying fluid towards and away from the integrated circuit, wherein the fluid is in thermal contact with the heat-exchange medium;
a magneto-hydrodynamic pump assembly operably coupled to the pipe and being configured to induce the fluid to move within the pipe;
a reservoir chamber containing additional fluid and connecting to a section of the pipe such that the fluid in the pipe enters and exits the reservoir chamber.

3. The computer apparatus of claim 1, the integrated-circuit cooling apparatus further comprising:
a heat sink thermally coupled to a hot-side of the thermoelectric cooling module.

4. A method of cooling an integrated circuit comprising:
circulating a fluid through a thermoelectric cooling module utilizing the Peltier effect, wherein the fluid is in thermal contact with a cold side of the thermoelectric cooling module and the integrated circuit;
circulating the fluid through a section of pipe extending outside of a computer case that at least partially encloses the integrated circuit.

5. The method of claim 4 further comprising:
coupling a heat-exchange medium to the integrated circuit;
magneto-hydrodynamically circulating fluid in the pipe to thereby circulate the fluid into contact with the heat exchange medium and through a reservoir chamber connected to the pipe, wherein the fluid entering the reservoir mixes with fluid in the reservoir.
